(19) United States
(12) Patent Application Publication
(10) Pub. No.: US 2004/0089862 A1
(43) Pub. Date: May 13, 2004

(54) Thin-film transistor, switching circuit, active element substrate, electro-optical device, electronic apparatus, thermal head, droplet ejecting head, printer, and thin-film-transistor driving and light-emitting display device

(75) Inventor: Mutsumi Kimura, Kyotanabe-shi (JP)

Correspondence Address: OLIFF & BERRIDGE, PLC, P.O. BOX 19928, ALEXANDRIA, VA, 22320, US

(73) Assignee: SEIKO EPSON CORPORATION, TOKYO (JP)

(21) Appl. No.: 10/615,014

(22) Filed: Jul. 9, 2003

(30) Foreign Application Priority Data
Jul. 10, 2002 (JP) 2002-201662
Aug. 29, 2002 (JP) 2002-251675

(51) Int. Cl. H01L 29/04; H01L 31/036

(52) U.S. Cl. 257/59; 257/72

(57) ABSTRACT

The invention reduces or prevents the performance of a driving thin-film transistor of a thin-film-transistor driving and light-emitting display device from deteriorating over time, while maintaining a function of allowing a large current to flow. In a driving thin-film transistor, a lightly doped region is provided only in a drain region (one-sided LDD structure). Alternatively, lightly doped regions are provided in both a source region and the drain region. The lightly doped region in the drain region is longer than the lightly doped region in the source region, resulting in an asymmetrical LDD structure.

### BACKGROUND OF THE INVENTION

1. Field of Invention

The present invention relates to thin-film transistors. More specifically, the invention relates to a thin-film transistor for use in applications requiring relatively large amounts of current (for example, applications of driving light-emitting elements, such as organic EL elements and the like).

2. Description of Related Art

The related art includes research, development, and commercialization of thin-film-transistor driving and light-emitting-diode display devices, which are one type of thin-film-transistor driving and light-emitting display devices. The related art is disclosed in: (T. Shimoda, M. Kimura, et al., Proc. Asia Display '98, 217; M. Kimura, et al., IEEE Trans. Electron. Devices 46 (1999), 2282; T. Shimoda, M. Kimura, et al., Dig. SID '99, 372; M. Kimura et al., Proc. Euro Display '99 Late-News Papers, 71; M. Kimura, et al., Proc. Euro Display '99 171; S. W. -B. Tam, M. Kimura, et al., Proc. IDW '99, 175; M. Kimura, et al., J. SID 8, 93 (2000); M. Kimura, et al., Dig. AM-LCD 2000, 245; and S. W. -B Tam, M. Kimura, et al., Proc. IDW 2000, 243).

FIG. 1 is a schematic circuit diagram of a pixel in a related art thin-film-transistor driving and light-emitting display device. A plurality of scanning lines 11 and a plurality of signal lines 12 are arranged in a matrix. At each of the intersections of the scanning lines 11 and the signal lines 12, a switching thin-film transistor 13, a driving thin-film transistor 14, and a light-emitting element 15 are provided. The switching thin-film transistor 13 samples the potential of the signal line 12 when the corresponding scanning line 11 has an ON potential. The driving thin-film transistor 14 controls the light-emitting state of the corresponding light-emitting element 15 on the basis of the potential sampled by the corresponding switching thin-film transistor 13.

FIG. 2 is a schematic of a driving thin-film transistor and a light-emitting element in the related art thin-film-transistor driving and light-emitting display device. In a driving thin-film transistor 21, an active region 23 and heavily doped regions 26 are directly connected to each other in both a source region 24 and a drain region 25 (self-aligned structure). With the self-aligned structure, the driving thin-film transistor 21 allows a large current to flow through a light-emitting element 31, thus achieving a high-intensity thin-film-transistor driving and light-emitting display device.

### SUMMARY OF THE INVENTION

Since the driving thin-film transistor 21 has the self-aligned structure, a large current is allowed to flow through the light-emitting element 31. The self-aligned structure has a tendency to deteriorate over time (S. Inoue, et al., Dig. SID '99, 452 and Y. Uraoka, et al., Dig. AM-LCD '01, 179). Since the driving thin-film transistor 21 allows a direct current to flow at all times, the driving thin-film transistor 21 tends to deteriorate over time.

The present invention reduces or prevents the performance of a thin-film transistor for use in a thin-film-transistor driving and light-emitting display device from deteriorating over time while maintaining a function of allowing a relatively large current to flow.

In order to address or achieve the above, a thin-film transistor of the present invention includes an active region, and a source region and a drain region provided at both sides of the active region. The source region and the drain region include regions adjacent to the active region, the adjacent regions including lightly doped impurity regions with an impurity concentration less than that of the drain region. The lightly doped impurity regions are provided in an asymmetrical form in which the lightly doped impurity region in the source region is smaller than that in the drain region.

By reducing the size of the lightly doped impurity region (LDD region) in the source region, the source/drain electric resistance is reduced, thus allowing a larger current to flow. The LDD region in the drain region has a certain area. Accordingly, generation of hot carriers (hot electrons) between the active region and the drain region is reduced or suppressed, reducing or preventing the performance of the thin-film transistor from deteriorating over time. In other words, according to the present invention, a thin-film transistor that satisfies two needs, that is, maintaining a function of allowing a relatively large current to flow and reducing or preventing the performance from deteriorating over time, is realized.

Preferably, the length, in the longitudinal direction of a channel, of the lightly doped impurity region in the drain region is longer than that of the lightly doped impurity region in the source region.

Preferably, the lightly doped impurity region is provided only in the drain region.

Preferably, the thin-film transistor further includes a gate electrode provided at a position facing the active region, with an insulating layer provided therebetween. The boundary between each lightly doped impurity region and the active region may approximately match one end of the gate electrode. The position at which the gate electrode is provided is determined on the basis of any of the following structures, including a bottom gate structure in which the gate electrode is provided below the active region (the substrate side) and a top gate structure in which the gate electrode is provided above the active region. In particular, the top gate structure makes it possible to have a so-called self-aligned gate structure in which a source region and a drain region are provided by ion implantation with the gate electrode serving as a mask.

A switching circuit of the present invention includes a first transistor that is provided in a load current path and that controls the load current and a second transistor that activates the first transistor in accordance with an input signal. The first and second transistors each have an LDD structure between a source and a drain. Lightly doped impurity regions that are responsible for the LDD structure of the first transistor are provided so that one in a source region is smaller than the other in a drain region, thus adjusting the source/drain resistance to increase the load current.

With the foregoing arrangement, the electric resistance between the source and the drain of the first transistor is reduced to increase the load current. Also, generation of hot carriers between the active region and the drain region is suppressed, preventing the performance of the thin-film transistor from deteriorating over time. Since the second transistor has the LDD structure, reliability is enhanced. A combination of the first and second thin-film transistors realizes a switching circuit that has a relatively high current driving capability and high reliability.

Preferably, the lightly doped impurity regions that are responsible for the LDD structure provided between the source and drain of the first transistor are provided asymmetrically between the source region and the drain region.

Preferably, the lightly doped impurity region that is responsible for the LDD structure provided between the source and the drain of the first transistor is provided only in the drain region.

According to the present invention, an active element substrate including the above-described switching circuit is provided. Specifically, an active element substrate of the present invention includes a plurality of scanning lines and a plurality of signal lines being provided on an insulating substrate so as to intersect with each other and a switching circuit to control a current to be supplied to a current load, the switching circuit being provided at each intersection of the scanning lines and the signal lines. The above-described switching circuit according to the present invention is used as the switching circuit.

According to the present invention, an electro-optical device including the above-described switching circuit is provided. Specifically, an electro-optical device of the present invention includes first and second electrodes that face each other; an electro-optical element provided between the first electrode and the second electrode; and a switching circuit that is connected to the first electrode and that controls a current to be supplied to the electro-optical element. The above-described switching circuit according to the present invention is used as the switching circuit.

Preferably, the above-described electro-optical element includes at least one of an electroluminescent element, an electrophotoluminescent element, a plasma light-emitting element, an electrophoresis element, and a liquid crystal element.

According to the present invention, an electronic apparatus is provided including the above-described electro-optical device according to the present invention serving as a display unit. Exemplary electronic apparatus include a video camera, a cellular phone, a personal computer, a personal digital assistant (PDA), and various other apparatuses, for example. By using the electro-optical device according to the present invention, an electronic apparatus with a display unit having excellent display characteristics is realized.

The above-described switching circuit according to the present invention is suitably applicable to a thermal head incorporated in a thermal transfer printer. Specifically, a thermal head of the present invention is a thermal head incorporated in a thermal transfer printer and includes a plurality of heating elements and a plurality of switching circuits to control the current to be supplied to the corresponding heating elements. The above-described switching circuit according to the present invention is used as the switching circuit.

The above-described switching circuit according to the present invention is suitably applicable to a droplet ejecting head (so-called inkjet head) used by being incorporated in an inkjet printer. Specifically, a droplet ejecting head of the present invention generates a bubble in a solution to be ejected by heat generated by a heating element and ejects the solution to be ejected from an ejection hole. The above-described switching circuit according to the present invention is used as a switching circuit to control the current to be supplied to the heating element.

According to the present invention, a printer is provided including the above-described thermal head or the droplet ejecting head according to the present invention.

The present invention also provides a thin-film-transistor driving and light-emitting display device including a plurality of scanning lines and a plurality of signal lines being provided in a matrix, and a switching thin-film transistor, a driving thin-film transistor, and a light-emitting element being provided at each intersection of the scanning lines and the signal lines. The switching thin-film transistor samples the potential of the signal line when the corresponding scanning line has an ON potential. The driving thin-film transistor controls the light-emitting state of the light-emitting element in accordance with the sampled potential. In the driving thin-film transistor, a lightly doped region is provided only in a drain region (one-sided LDD structure).

The present invention also provides a thin-film-transistor driving and light-emitting display device including a plurality of scanning lines and a plurality of signal lines being provided in a matrix, and a switching thin-film transistor, a driving thin-film transistor, and a light-emitting element being provided at each intersection of the scanning lines and the signal lines. The switching thin-film transistor samples the potential of the signal line when the corresponding scanning line has an ON potential. The driving thin-film transistor controls the light-emitting state of the light-emitting element in accordance with the sampled potential. Lightly doped regions are provided in both a source region and a drain region. The length of the lightly doped region in the drain region is longer than the length of the lightly doped region in the source region (asymmetrical LDD structure).

In general, the LDD structure prevents deterioration over time (Takayuki Ohno, Yukiharu Uraoka, et al., Shingakugihou (Technical Report of IEICE) ED2000-7, 43(2000)). Since the present invention employs the one-sided LDD structure or the asymmetrical LDD structure, the driving thin-film transistor of the thin-film-transistor driving and light-emitting display device maintains the function of allowing a large current to flow while being prevented from deteriorating over time. Since the current direction of the light-emitting element is determined, the source region side and the drain region side of the driving thin-film transistor are determined. Therefore, there will be no confusion as to the providing of the one-sided LDD structure or the asymmetrical LDD structure.

Compared with a both-sided LDD structure, the present invention can allow a large current to flow even when the driving thin-film transistor applies a low voltage. The voltage applied to the scanning lines and the signal lines can be reduced, and hence the power consumption of a built-in drive circuit and an external drive circuit can be reduced. Furthermore, narrowing of the driving thin-film transistor is made possible, leading to enhancement of the light-emitting region ratio (the ratio of the light-emitting region to the entire pixel area), reduction of the current density of the light-emitting element, and elongation of life of the light-emitting element.

### BRIEF DESCRIPTION OF THE DRAWINGS

FIG. 1 is a schematic circuit diagram of a pixel in a related art thin-film-transistor driving and light-emitting display device;

FIG. 2 is a schematic of a driving thin-film transistor and a light-emitting element in the related art thin-film-transistor driving and light-emitting display device;

FIG. 3 is a schematic of a driving thin-film transistor and a light-emitting element according to a first aspect of the present invention;

FIG. 4 is a schematic of a driving thin-film transistor and a light-emitting element according to a second aspect of the present invention;

FIG. 5 is a schematic describing the length of a lightly doped region in a drain region and the length of a lightly doped region in a source region;

FIG. 6 is a schematic circuit diagram of a display device;

FIGS. 7(a)-7(d) are schematics of specific examples of electronic apparatuses to which the display device is applicable;

FIG. 8 is a schematic of a heating-element control circuit;

FIG. 9 is a schematic of the circuit configuration of a heating-element array;

FIGS. 10(a) and 10(b) are schematics of a specific example of a thermal head;

FIGS. 11(a) and 11(b) are schematics of a exemplary inkjet head.

### DETAILED DESCRIPTION OF PREFERRED EMBODIMENTS

Exemplary embodiments of the present invention are described below with reference to the drawings. In the present specification, a thin-film transistor used to allow a relatively large current to flow is referred to as a “driving thin-film transistor”.

### First Exemplary Embodiment

FIG. 3 is a schematic of a driving thin-film transistor and a light-emitting element according to a first exemplary embodiment of the present invention. As shown in FIG. 3, in a driving thin-film transistor 21 of the first exemplary embodiment, a lightly doped region 27 is provided only in a drain region 25, resulting in a one-sided LDD (lightly Doped Drain) structure.

More specifically, as shown in FIG. 3, the driving thin-film transistor 21 is to control a current to be supplied to a light-emitting element 31 and is provided on a substrate 20. Although an organic EL (electroluminescent) element is used as the light-emitting element 31 in this exemplary embodiment, the light-emitting element 31 is not limited to this type.

The driving thin-film transistor 21 includes a gate electrode 22, an active region 23, a source region 24, and the drain region 25.

The active region 23 is provided on the substrate 20 at a position approximately facing the gate electrode 22. The active region 23 functions as a current path. An insulating layer made of SiO₂ or the like is provided between the active region 23 and the gate electrode 22.

The source region 24 includes a heavily doped region 26 that is heavily doped with impurities (dopant). The heavily doped region 26 is connected via a source electrode to a current source (not shown).

The drain region 25 includes a heavily doped region 26 that is heavily doped with impurities and the lightly doped region (lightly doped impurity region) 27 that is lightly doped with impurities. The heavily doped region 26 is connected via a drain electrode to the light-emitting element 31.

One end of the lightly doped region 27 is connected to the active region 23, and the other end of the lightly doped region 27 is connected to the heavily doped region 26. As shown in FIG. 3, the boundary between the active region 23 and the lightly doped region 27 approximately matches one end of the gate electrode 22.

As discussed above, in the driving thin-film transistor 21 of the first exemplary embodiment, no lightly doped region (LDD region) is provided in the source region 24, and the lightly doped region (LDD region) 27 is provided only in the drain region 25, thus realizing an asymmetrical LDD structure. Accordingly, the electric resistance between source and drain is reduced to allow a larger current to flow. At the same time, generation of hot carriers between the active region 23 and the drain region 25 is reduced or suppressed, thus reducing or preventing the performance of the thin-film transistor from deteriorating over time.

### Second Exemplary Embodiment

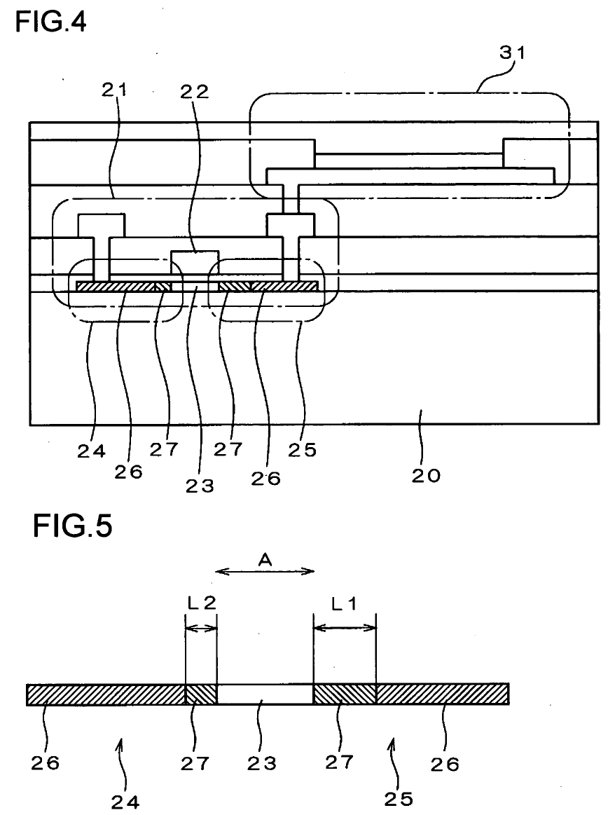

FIG. 4 is a schematic of a driving thin-film transistor and a light-emitting element according to a second exemplary embodiment of the present invention. As shown in FIG. 4, in the driving thin-film transistor 21, the lightly doped regions 27 are provided in both the source region 24 and the drain region 25. The lightly doped region 27 in the drain region 25 is longer than the lightly doped region 27 in the source region 24, resulting in an asymmetrical LDD structure. In the driving thin-film transistor 21 shown in FIG. 4, the same reference numerals are given to components corresponding to those of the first exemplary embodiment, and detailed descriptions of the common portions are omitted.

In the driving thin-film transistor 21 shown in FIG. 4, the source region 24 includes the heavily doped region 26, which is heavily doped with impurities, and the lightly doped region 27, which is lightly doped with impurities. One end of the lightly doped region 27 is connected to the active region 23, and the other end of the lightly doped region 27 is connected to the heavily doped region 26. As shown in FIG. 4, the boundary between the active region 23 and the lightly doped region 27 approximately matches one end of the gate electrode 22.

The drain region 25 includes the heavily doped region 26, which is heavily doped with impurities, and the lightly doped region 27, which is lightly doped with impurities. One end of the lightly doped region 27 is connected to the active region 23, and the other end of the lightly doped region 27 is connected to the heavily doped region 26. As shown in FIG. 4, the boundary between the active region 23 and the lightly doped region 27 approximately matches the other end of the gate electrode 22.

FIG. 5 is a schematic describing the length of the lightly doped region 27 in the drain region 25 and the length of the lightly doped region 27 in the source region 24. In FIG. 5, a range covering the lightly doped regions 27 is enlarged.

As shown in FIG. 5, in this exemplary embodiment, the lightly doped regions 27 are provided so that length L1, in the longitudinal direction of the channel (A direction in the illustration), of the lightly doped region 27 in the drain region 25 is greater than length L2, in the longitudinal direction of the channel, of the lightly doped region 27 in the source region 24. The lightly doped regions 27 are provided so that the cross sectional areas of faces orthogonal to the current direction (faces orthogonal to the page) are approximately equal.

As discussed above, in the driving thin-film transistor 21 of the second exemplary embodiment, the lightly doped regions 27 differ from each other in length, in the longitudinal direction of the channel, resulting in an asymmetrical LDD structure. Accordingly, the electric resistance between source and drain is reduced to allow a larger current to flow. At the same time, generation of hot carriers between the active region 23 and the drain region 25 is reduced or suppressed, thus reducing or preventing the performance of the thin-film transistor from deteriorating over time.

### Third Exemplary Embodiment

Using the driving thin-film transistor 21 according to the present invention, which is described in the first or second exemplary embodiment, a switching circuit that allows a relatively large current to flow and that deteriorates slowly over time is provided. Such a switching circuit is suitable to drive a light-emitting element, such as an organic EL element. A specific example of a pixel circuit using the switching circuit according to the present invention is described below.

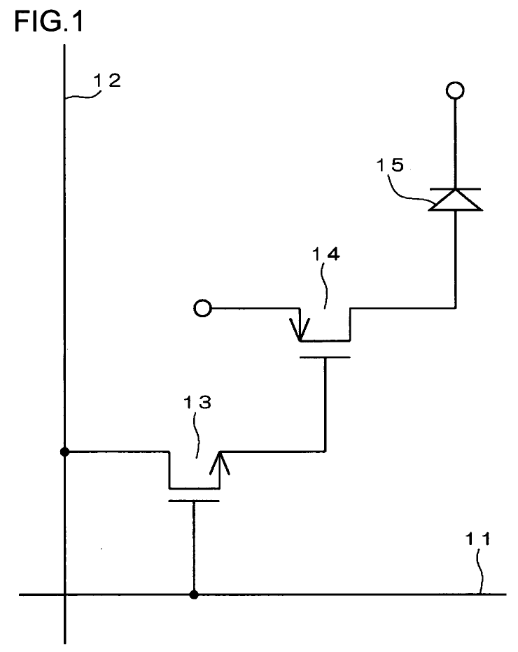

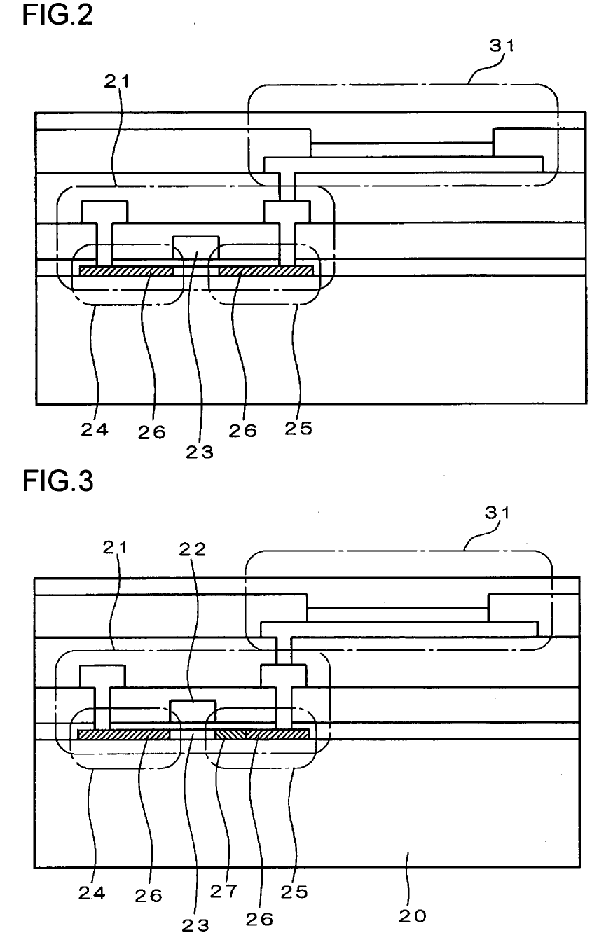

Since the circuit structure of a pixel circuit of a third exemplary embodiment is basically similar to the equivalent circuit of the pixel, which is shown in FIG. 1, the pixel circuit of the third exemplary embodiment is not shown. In the equivalent circuit of the pixel, which is shown in FIG. 1, the driving thin-film transistor 21 according to the present invention, which is described in the first or second exemplary embodiments, is used in place of the driving thin-film transistor 14. Accordingly, a pixel circuit that has a relatively high current driving capability and high reliability can be realized.

When a pixel circuit having a structure similar to that shown in FIG. 1 is provided using the driving thin-film transistor 21 of the first or second exemplary embodiments, a switching thin-film transistor 13 to switch on/off the driving thin-film transistor 21 may have an LDD structure. In this case, the LDD structure of the switching thin-film transistor 13 may be asymmetrical, as in the case with the driving thin-film transistor 21, or may be symmetrical. In this case, the LDD structures of both the switching thin-film transistor 13 and the driving thin-film transistor 21 are constructed by the same manufacturing process. Therefore, the manufacturing process is not extended.

An element (current load) whose load current is to be controlled by the switching circuit of this exemplary embodiment is not limited to the above-described organic EL element, but is also applicable to various electro-optical elements, such as an electrophotoluminescent element, a plasma light-emitting element, an electrophoresis element, and a liquid crystal element.

An active element substrate that includes the above-described driving thin-film transistor and a display device (electro-optical device) that includes such an active element substrate will now be described.

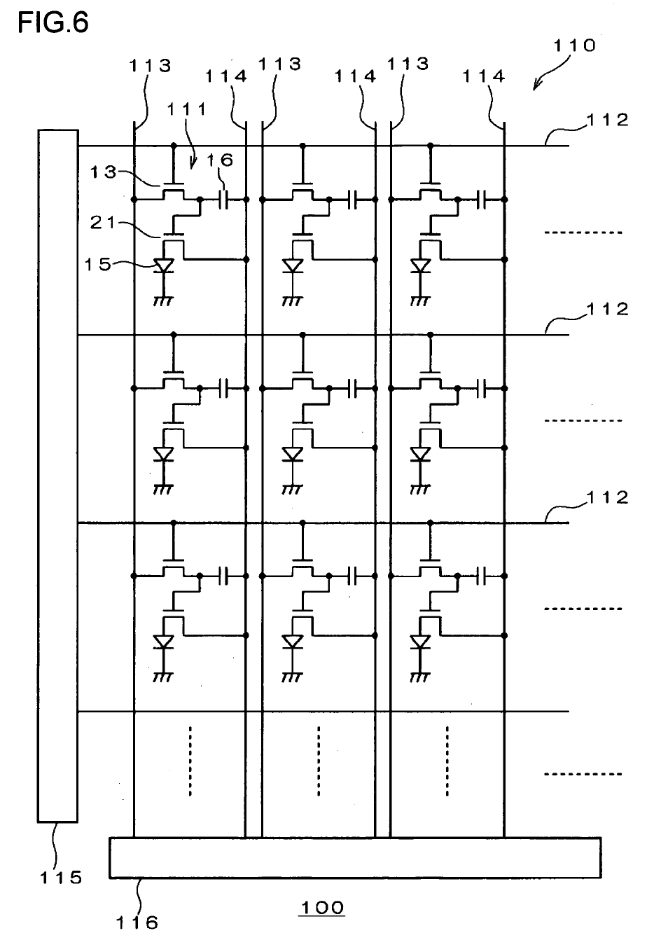

FIG. 6 is a schematic of an equivalent circuit diagram of a display device. As shown in FIG. 6, a display device 100 includes a plurality of pixel portions 111 arranged in a matrix in a display region 110, a plurality of scanning lines 112, a plurality of signal lines 113, a plurality of power lines 1 14, and drivers 115 and 1 16.

Each of the pixel portions 111 includes the above-described pixel circuit. Specifically, each pixel portion 111 includes the switching thin-film transistor 13, the light-emitting element 15, a storage capacitor 16, and the driving thin-film transistor 21.

The driver 115 supplies a control signal to the gate of the switching thin-film transistor 13 included in each pixel portion 111 via the corresponding scanning line 112. The drive 116 supplies a control signal to the source of the switching thin-film transistor 13 included in each pixel portion 111 via the corresponding signal line 113 and supplies a current to the source of the driving thin-film transistor 21 included in each pixel portion 111 via the corresponding power line 114.

In other words, the display device 100 shown in FIG. 6 includes an array substrate (active element substrate) on which the light-emitting elements 15 serving as the current loads and the like are provided. The array substrate includes the plurality of scanning lines 112 and the plurality of signal lines 113 intersecting with each other and, at each of the intersections of the scanning lines 112 and the signal lines 113, a switching circuit including the switching thin-film transistor 13 and the driving thin-film transistor 21. In other words, the active element substrate prior to its being mounted with the light-emitting element and the like may be an independent product, to which the present invention can be applied.

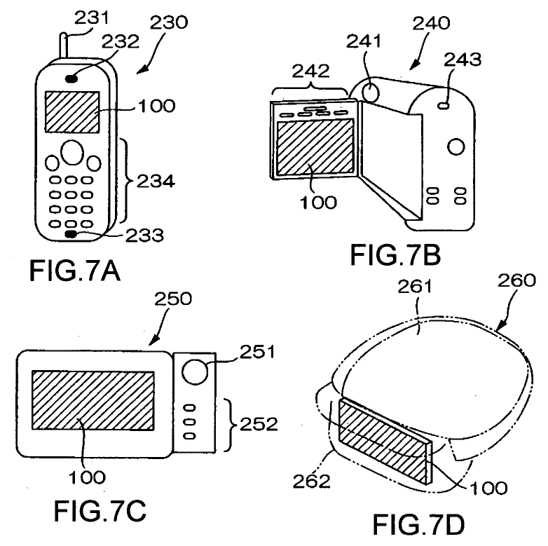

Various electronic apparatuses including the above-described display device 100 are described below. FIGS. 7(a)-7(d) are schematics of specific examples of electronic apparatuses to which the display device 100 is applicable.

FIG. 7(a) shows an application to a cellular phone. A cellular phone 230 includes an antenna 231, an audio output unit 232, an audio input unit 233, an operation unit 234, and the display device 100 of the present invention. As discussed above, the display device according to the present invention can be used as a display unit.

FIG. 7(b) shows an application to a video camera. A video camera 240 includes an image receiving unit 241, an operation unit 242, an audio input unit 243, and the display device 100 of the present invention. As discussed above, the display device according to the present invention can be used as a finder or a display unit.

FIG. 7(c) shows an application to a mobile personal computer. A computer 250 includes a camera 251, an operation unit 252, and the display device 100 of the present invention. As discussed above, the display device according to the present invention can be used as a display unit.

FIG. 7(d) shows an application to a head mounted display. A head mounted display 260 includes a band 261, an optical system storage section 261, and the display device 100 of the present invention. As discussed above, the display device according to the present invention can be used as an image display source.

The display device 100 according to the present invention is applicable not only to the above-described examples, but also to various electronic apparatuses including a facsimile machine with a display function, a finder of a digital camera, a portable TV, and an electronic notebook.

### Fourth Exemplary Embodiment

Another example of a switching circuit including the driving thin-film transistor 21 described in the first or second exemplary embodiments is a circuit to control the current that flows through a heating element (hereinafter “heating-element control circuit”). Such a heating-element control circuit is used in a print head (thermal head) in a thermal transfer printer (thermal printer) or the like. A specific description of the heating-element control circuit is provided below.

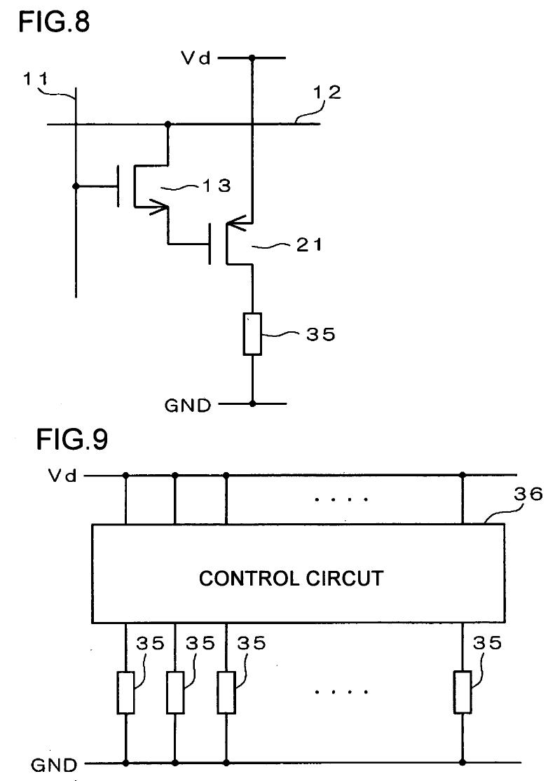

FIG. 8 is a schematic of a heating-element control circuit. In the heating-element control circuit shown in FIG. 8, the light-emitting element 15 in the pixel circuit described in the third exemplary embodiment is replaced by a heating element 35.

Specifically, a switching circuit including the switching thin-film transistor 13 and the driving thin-film transistor 21 is provided at the intersection of the scanning line 11 and the signal line 12. The switching circuit controls the current that flows through the heating element 35.

When the heating-element control circuit shown in FIG. 8 includes the driving thin-film transistor 21 according to the first or second exemplary embodiments, the switching thin-film transistor 13 may have an LDD structure. In this case, the LDD structure of the switching thin-film transistor 13 may be asymmetrical, as in the driving thin-film transistor 21, or may be symmetrical.

A heating-element array including the heating-element control circuit described above is described below. FIG. 9 is a schematic of the circuit configuration of a heating-element array. The heating-element array shown in FIG. 9 includes a plurality of heating elements 35 and a control circuit 36 to control the current that flows through each of the heating elements 35. The control circuit 36 includes a plurality of heating-element control circuits (see FIG. 8), the number of which corresponds to the number of heating elements 35.

The heating-element array shown in FIG. 9, prior to its being mounted with the heating elements 35, may be provided as an independent product serving as an array substrate that includes a plurality of switching circuits including a plurality of switching thin-film transistors 13 and a plurality of driving thin-film transistors 21.

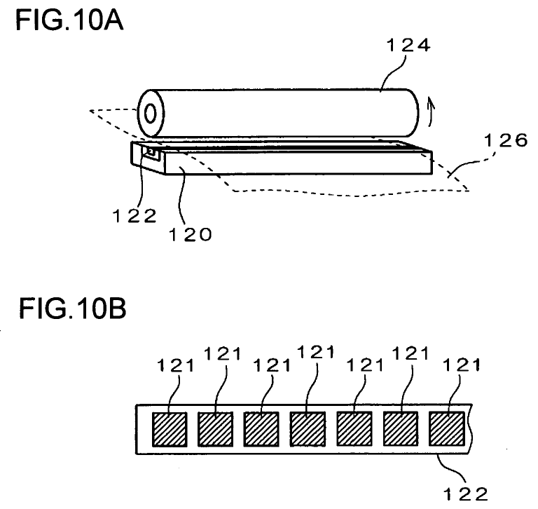

A specific example of a thermal head for use in a thermal printer, which includes the above-described heating-element control circuit, is described below. FIGS. 10(a) and 10(b) are schematics of a specific example of a thermal head. FIG. 10(a) is a perspective view schematically describing a thermal head according to the present invention. FIG. 10(b) is a plan view describing a heating-element array included in the thermal head.

A thermal head 120 shown in FIGS. 10(a) and 10(b) is used by being incorporated in a thermal printer. The thermal head 120 includes a heating-element array 122 that includes a plurality of heating elements 121. A thermal print medium (such as thermal paper) 126 is held between the thermal head 120 and a feed roller 124. The thermal head 120 applies heat to an arbitrary position on the print medium 126, and printing is performed. The heating-element array 122 includes the structure shown in FIG. 9. As shown in FIG. 10(b), the heating-element array 122 includes the plurality of heating elements 121 arranged in a line and a control circuit (not shown) to drive each of the heating elements 121. A thermal printer (not shown) can be provided using the thermal head 120.

The above-described thermal head 120 is also applicable to a case in which a thermal recording material (so-called ink ribbon) is provided between the thermal head 120 and the print medium 126, and printing is performed by transferring the thermal recording material to a non-thermal print medium.

Using the above-described heating-element control circuit, an inkjet head (droplet ejecting head) may be provided that employs a so-called thermal inkjet method to eject ink by generating bubbles in a solution to be ejected (hereinafter “ink”) by heat generated by heating elements. The inkjet head is described in detail below.

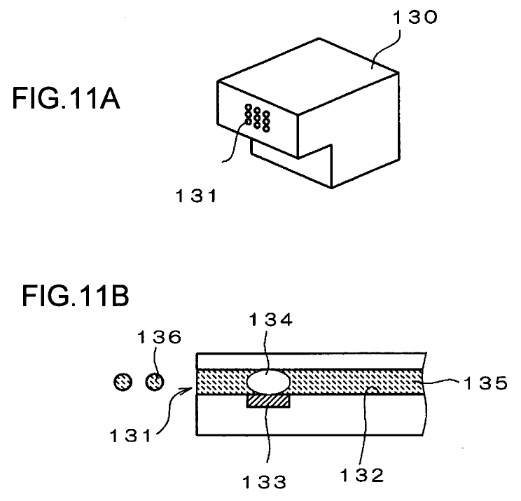

FIGS. 11(a) and 11(b) are schematics of an exemplary inkjet head. FIG. 11(a) is a perspective view schematically describing an inkjet head according to the present invention. FIG. 11(b) is a sectional view of a portion corresponding to one of ejection holes 131, illustrating a heating element included in the inkjet head.

An inkjet head 130 shown in FIGS. 11(a) and 11(b) is used by being incorporated in a thermal inkjet printer. The inkjet head 130 includes the plurality of ejection holes 131 and heating elements 133 corresponding to the respective ejection holes 131.

As shown in FIG. 11(b), the ejection hole 131 and an ink path 132 are linked together so that they communicate with one another. The heating element 133 is provided near the ejection hole 131 in the ink path 132. When a current is supplied to the heating element 133, heat generated by the heating element 133 generates a bubble 134 in ink 135 in the ink path 132, which in turn causes droplets 136 to be ejected from the ejection hole 131.

As described above, the plurality of heating elements 133 is provided, the number of which corresponds to the number of ejection holes 131. The current supplied to each of the heating elements 133 is controlled independently. The heating-element control circuit shown in FIG. 8 is applicable to a heating-element control circuit that includes the plurality of heating elements 133 and a control circuit (not shown) to drive each of the heating elements 133. A thermal inkjet printer (not shown) can be provided using the inkjet head 130.

The above-described inkjet head 130 is applicable not only to a printer, but also applicable to, for example, a droplet ejecting apparatus that supplies a desired solution (such as a plating solution or a photo-resist solution) to a desired position in a semiconductor-device manufacturing process or the like.

The present invention is not limited to the contents of the above-described exemplary embodiments. Various modifications can be made within the scope of the present invention. For example, in the first and second exemplary embodiments, the conductive type of the driving thin-film transistor 21 is p-type, and a current flows through the light-emitting element 31 in the direction from the driving thin-film transistor 21 to the light-emitting element 31. Therefore, the drain region 25 is provided at a location connected to the light-emitting element 31. In contrast, if the conductive type of the driving thin-film transistor 21 is n-type or if a current flows through the light-emitting element 31 in the direction from the light-emitting element 31 to the driving thin-film transistor 21, the drain region 25 is provided at a location that is not connected to the light-emitting element 31. Accordingly, the one-sided LDD structure or the asymmetrical LDD structure must be provided.

### Advantages

As described above, according to the present invention, a thin-film transistor that satisfies two needs, that is, maintaining a function of allowing a relatively large current to flow and reducing or preventing deterioration over time, is realized.

According to the present invention, a switching circuit that has a relatively high current driving capability and high reliability is realized.

What is claimed is:

1. A thin-film transistor, comprising:
an active region;
a source region; and
a drain region, the source region and the drain region being provided at each side of the active region, respectively;
the source region and the drain region including regions adjacent to the active region, the adjacent regions including lightly doped impurity regions with an impurity concentration less than an impurity concentration of the drain region; and
the lightly doped impurity regions being provided in an asymmetrical form in which the lightly doped impurity region in the source region is smaller than the drain region.

2. The thin-film transistor according to claim 1, the length, in the longitudinal direction of a channel, of the lightly doped impurity region in the drain region being longer than the lightly doped impurity region in the source region.

3. A thin-film transistor, comprising:
an active region;
a source region; and
a drain region, the source region and the drain region being provided at each side of the active region, respectively;
wherein only the drain region includes region adjacent to the active region, the adjacent region includes LDD with an impurity concentration less than an impurity concentration of the drain region.

4. The thin-film transistor according to claim 1, further including a gate electrode provided at a position facing the active region, with an insulating layer provided therebetween,
the boundary between each lightly doped impurity region and the active region approximately matching one end of the gate electrode.

5. A switching circuit, comprising:
a first transistor provided in a load current path and controlling the load current;
a second transistor activating the first transistor in accordance with an input signal, the first and second transistors each having an LDD structure between a source and a drain; and
lightly doped impurity regions responsible for the LDD structure of the first transistor being provided so that one in a source region is smaller than the other in a drain region, thus adjusting the source/drain resistance to increase the load current.

6. The switching circuit according to claim 5, the lightly doped impurity regions that are responsible for the LDD structure provided between the source and drain of the first transistor being provided asymmetrically between the source region and the drain region.

7. A switching circuit, comprising:
a first transistor provided in a load current path and that controls the load current;
a second transistor activating the first transistor in accordance with an input signal, the first and second transistors each having an LDD structure between a source and a drain; and
wherein the LDD structure of the first transistor is set so that a lightly doped impurity region which is responsible for the LDD structure is provided only between the drain region and an active region of the first transistor.

8. An active element substrate, comprising:
an insulated substrate;
a plurality of scanning lines and a plurality of signal lines provided on the insulated substrate so as to intersect with each other; and
the switching circuit according to claim 5, the switching circuit controlling a current to be supplied to a current load, the switching circuit being provided at each intersection of the scanning lines and the signal lines.

9. An electro-optical device, comprising:
first and second electrodes that face each other;
an electro-optical element provided between the first electrode and the second electrode; and
the switching circuit according to claim 5, the switching circuit being connected to the first electrode and controlling a current to be supplied to the electro-optical element.

10. The electro-optical device according to claim 9, the electro-optical element including at least one of an electroluminescent element, an electrophotoluminescent element, a plasma light-emitting element, an electrophoresis element, and a liquid crystal element.

11. An electronic apparatus, comprising:
the electro-optical device according to claim 9 serving as a display unit.

12. A thermal head incorporated in a thermal transfer printer, comprising:
a plurality of heating elements; and
a plurality of switching circuits to control current to be supplied to corresponding heating elements, each of the plurality of switching circuits including the switching circuit according to claim 5.

13. A droplet ejecting head to generate a bubble in a solution to be ejected, comprising:
a heating element generating heat to generate the bubble;
an ejection hole through which solution is ejected; and
the switching circuit according to claim 5 used to control current to be supplied to the heating element.

14. A printer, comprising:
the thermal head according to claim 12.

15. A printer, comprising:
the droplet ejecting head according to claim 13.

16. A thin-film-transistor driving and light-emitting display device, comprising:
a plurality of scanning lines and a plurality of signal lines provided in a matrix; and
a switching thin-film transistor, a driving thin-film transistor, and a light-emitting element provided at each intersection of the scanning lines and the signal lines, the switching thin-film transistor sampling a potential of the signal line when the corresponding scanning line has an ON potential, the driving thin-film transistor controlling a light-emitting state of the light-emitting element in accordance with the sampled potential, and a lightly doped region being provided in the driving thin-film transistor only in a drain region.

17. A thin-film-transistor driving and light-emitting display device, comprising:
a plurality of scanning lines and a plurality of signal lines provided in a matrix; and
a switching thin-film transistor, a driving thin-film transistor, and a light-emitting element provided at each intersection of the scanning lines and the signal lines, the switching thin-film transistor sampling a potential of the signal line when the corresponding scanning line has an ON potential, the driving thin-film transistor controlling a light-emitting state of the light-emitting element in accordance with the sampled potential, lightly doped regions provided in the driving thin-film transistor in both a source region and a drain region, and a length of the lightly doped region in the drain region being longer than a length of the lightly doped region in the source region.
